(19) United States
(12) Patent Application Publication
(10) Pub. No.: US 2004/0130877 A1
(43) Pub. Date: Jul. 8, 2004

(54) Substrate for high-frequency module and high-frequency module

(76) Inventor: Akihiko Okubora, Kanagawa (JP)

Correspondence Address: Holland & Knight, 30th Floor, 131 South Dearborn Street, Chicago, IL, 60603, US

(21) Appl. No.: 10/472,325

(22) PCT Filed: Jan. 24, 2003
(86) PCT No.: PCT/JP03/00682

(30) Foreign Application Priority Data
Jan. 25, 2002 (JP) 2002-17619

(51) Int. Cl. H05K 1/11; H05K 1/14

(52) U.S. Cl. 361/793

(57) ABSTRACT

A high-frequency module having a communication function is provided which uses a circuit board including an organic substrate (5) formed from a woven glass fabric (21) formed by weaving glass fibers (22) into a mesh pattern and also an organic material (20) provided integrally on the woven glass fabric (21) as a core. The organic substrate (5) has the glass fibers (22) distributed at close intervals of λe/4 (λe: effective wavelength of high-frequency signal) in the wavelength traveling direction of the high-frequency signal in the conductor patterns where resonant lines for transmission of the high-frequency and passive elements are formed. In the high-frequency module, the “variations” of the dielectric constant etc. of the organic substrate, which would be caused by any thick and thin distributions of the glass fibers, can be reduced, and thus the conductive parts can work with stable performances, respectively.

### TECHNICAL FIELD

The present invention relates to a high-frequency module installed fixedly or removably as an ultra-small communication module in an electronic device such as a personal computer, personal digital assistant, module telephone or an audio device, and also to a circuit board used in the high-frequency module.

This application claims the priority of the Japanese Patent Application No. 2002-017619 filed on Jan. 25, 2002, the entirety of which is incorporated by reference herein.

### BACKGROUND ART

Conventionally, audio or video information is digitized for easy treatment in a personal computer, various mobile devices or the like. Namely, digital data can easily be recorded, reproduced or transmitted without being deteriorated in quality. Such digital audio or video information can be band-compressed by the audio and video codec techniques for easier and more efficient distribution to a variety of communication terminals by a digital communication and broadcasting. For example, audio and video data (AV data) can be received by a mobile telephone out of doors.

Recently, transmission/reception systems for such digital information are practically used in various manners since there have been proposed network systems suitable for outdoor use as well as for use in a small-scale area. As such network systems, there have been proposed, in addition to a weak radio-wave system using a frequency band of 400 MHz and personal handy-phone system (PHS) using a frequency band of 1.9 GHz, various types of next-generation radio communication systems including a radio LAN system using a frequency band of 2.45 GHz and small-scale radio communication system called “Bluetooth”, both proposed in IEEE 802.11b, and a narrow-band radio communication system using a frequency band of 5 GHz proposed in IEEE 802.11a. With the effective use of such various radio communication system and also various types of communication terminals, the digital information transmission/reception systems can transfer and receive various kinds of data by various types of communication terminals in various places, for example, in doors, out of doors or the like, access a communication network such as the Internet, and transmit and make data transmission and reception to and from the communication network. However, the above data communications can be done easily, not via any repeater or the like.

However, the communication terminal having the above communication functions for the digital information transmission/reception systems should essentially be compact and lightweight, and portable. Since the communication terminal has to modulate and demodulate analog high-frequency signals in a transmission/reception block thereof, it generally includes a high-frequency transmission/reception circuit of a superheterodyne type designed to convert the signal frequency into an intermediate frequency once for transmission or reception.

The high-frequency transmission/reception circuit includes an antenna block having an antenna and a select switch and which receives or transmits information signals, and a transmission/reception selector which makes a selection between transmission and reception modes of operation. The high-frequency transmission/reception circuit also includes a reception circuit block composed of a frequency convert circuit, demodulation circuit, etc. The high-frequency transmission/reception circuit further includes a transmission circuit block composed of a power amplifier, drive amplifier, modulation circuit, etc. The high-frequency transmission/reception circuit also includes a reference frequency generation circuit block which supplies a reference frequency to the reception and transmission circuit blocks.

The above-mentioned high-frequency transmission/reception circuit is composed of many parts including large functional components such as various filters interposed between stages, local oscillator (VCO), surface acoustic wave (SAW) filter and the like, and passive components such as an inductor, capacitor, resistor and the like provided peculiarly to high-frequency analog circuits like a matching circuit, bias circuit, etc. In the high-frequency transmission/reception circuit, each of the circuit blocks is implemented in IC-chip form. However, since each of the filters interposed between the stages cannot be assembled in any IC, the matching circuit has to be provided as an external device for the high-frequency transmission/reception circuit. Therefore, the high-frequency transmission/reception circuit as a whole is so large that the communication terminal cannot be designed compact and lightweight.

On the other hand, some-communication terminals use a direct conversion-type high-frequency transmission/reception circuit which transmits and receives information signals without conversion of the signal frequency into an intermediate frequency. In this high-frequency transmission/reception circuit, information signals received by the antenna block are supplied through the transmission/reception selector to the demodulation circuit where they will undergo a direct baseband processing. In the high-frequency transmission/reception circuit, information signals generated by a source have the frequency thereof not converted once by the modulation circuit into any intermediate frequency but modulated directly to a predetermined frequency band, and sent from the antenna block via the amplifier and transmission/reception selector.

Since the above high-frequency transmission/reception circuit is constructed to transmit and receive information signals with the direction modulation of the signal frequency but without conversion of the signal frequency into any intermediate frequency, it can be composed of a reduced number of parts such as the filter etc. so simply as to have a generally one-chip construction. Also, in the high-frequency transmission/reception circuit of the direct conversion type, something has to be done about the filter or matching circuit provided in the downstream stage. In the high-frequency transmission/reception circuit, since signals are amplified once in the high-frequency stage, it is difficult to make a sufficient gain. So, it is necessary to make amplification of the signals in the base-band processing block as well. Therefore, a DC offset cancel circuit and an extra lowpass filter have to be provided in the high-frequency transmission/reception circuit, which will lead to a larger total power consumption.

The conventional high-frequency transmission/reception circuit, whether of the aforementioned superheterodyne type or of the direct conversion type, does not meet the requirements for the compact and lightweight design of the communication terminals. On this account, various approaches have been made to design a more compact and lightweight high-frequency transmission/reception circuit by designing a simple-construction high-frequency transmission/reception module on the basis of the Si-CMOS technique, for example. In a typical example of such approaches, the high-frequency module is built in a one-chip form by forming passive elements each having a good performance on an Si substrate while forming a filter circuit and resonator in an LSI and integrating an logic LSI for the baseband processing circuit. Since the Si substrate is electrically conductive, however, it is difficult to form an inductor and capacitor each having a high Q value on the main side of the Si substrate. In this case, such approaches essentially depend upon how higher-performance passive elements are formed on the Si substrate.

FIGS. 1A and 1B show together a conventional high-frequency module. The high-frequency module is generally indicated with a reference 100. It includes a silicon substrate 101, SiO₂ insulative layer 102, first wiring layer 105, second wiring layer 106 and an inductor 107. The assembly of the silicon substrate 101 and SiO₂ insulative layer 102 has formed therein a large concavity 104 which defines a place (indicated at a reference 103) where the inductor 107 is to be formed. The first wiring layer 105 is formed in the concavity 104. The second wiring layer 106 is formed on the top of the silicon layer 101 and the inductor 107 itself is provided over the concavity 104. Since the inductor 107 faces the concavity 104 and is supported by the second wiring layer 106 in air over the concavity 103, its electrical interference with the circuit inside via the silicon substrate 101 is smaller, so that the high-frequency module 100 has an improved performance. However, the inductor 107 included in this high-frequency module 100 is formed through many difficult processes and with an increased manufacturing cost.

FIG. 2 shows a conventional silicon substrate. As shown, the silicon substrate, generally indicated with a reference 110, includes a silicon substrate 111, SiO₂ layer 112 formed on the silicon substrate 111, and a passive element forming layer 113 formed on the SiO2 layer 111 by the photolithography. The high-frequency module 110 has passive elements such as an inductor, capacitor or resistor formed in multiple layers, each along with a wiring element, in the passive element forming layer 113 with the thing-film and thick-film forming techniques, which will not be described in detail herein. In the high-frequency module 110, the passive element forming layer 113 has a via hole 114 formed appropriately therethrough for an interlayer connection and a terminal 115 formed on the surface layer thereof A chip 116 such as a high-frequency IC, LSI or the like is mounted on the high-frequency module 110 on contact with the terminal 115 by the flip chip bonding or the like to form a high-frequency circuit.

Such a high-frequency module 110 is mounted on an interposer circuit board or the like having a base band circuit and the like formed thereon to make an isolation between the passive element forming layer and the base band circuit by means of the silicon layer 111, thereby permitting to suppress an electric interference between the passive element forming layer and the base band circuit. Since the silicon layer 111 is electrically conductive, the high-frequency module 110 can effectively function when a high-precision passive element is formed in the passive element forming layer 113. On the other hand, however, the silicon layer 111 being electrically conductive will inhibit each of passive elements from a having good high-frequency performance.

FIG. 3 shows another conventional high-frequency module. The high-frequency module, generally indicated with a reference 120, uses a substrate 121 not electrically conductive such as a glass substrate or ceramic substrate to overcome the above-mentioned drawbacks of the aforementioned silicon substrate 111. As shown, this high-frequency module 120 includes a substrate 121 and a passive element forming layer 122 formed on the substrate 121 by the photolithography. Similarly to the aforementioned conventional high-frequency module 110, the high-frequency module 120 has passive elements such as an inductor, capacitor or resistor formed in multiple layers, along with a wiring element, in the passive element forming layer 122 with the thing-film and thick-film forming techniques, which will not be described in detail herein. In the high-frequency module 120, the passive element forming layer 122 has a via hole 123 formed appropriately therethrough for an interlayer connection and a terminal 124 formed on the surface layer thereof. A high-frequency IC 125, chip-shaped part 126 or the like is mounted on the high-frequency module 120 with the terminal 124 laid between them by the flip chip bonding or the like to form a high-frequency circuit.

In the high-frequency module 120 shown in FIG. 3, since use of the substrate 121 not electrically conductive inhibits the capacitive coupling between the substrate 121 itself and passive element forming layer 122, a passive element having a good high-frequency performance can be formed in the passive element forming layer 122. In case the high-frequency module 120 is formed from a glass substrate, however, since no terminal can be formed on the substrate 121 itself when the high-frequency module 120 is mounted on a mother board or the like,.a terminal pattern has to be formed on the surface of the passive element forming layer 122 to connect the high-frequency module 120 to the mother board by the wire bonding technique or the like. Therefore, the processes of producing the high-frequency module 120 include the terminal pattern forming process and wire bonding process, which causes the manufacturing cost to be higher and is not advantageous for attaining a compact and lightweight design of the high-frequency module 120.

On the other band, in case the high-frequency module 120 is formed from a ceramic substrate, it functions as a package board on no contact with any mother board because ceramic substrates can be formed in multiple layers. Since the ceramic substrate is formed from sintered ceramic particles, it will have, on a surface thereof where the passive element forming layer 122 is formed, a roughness as large as the ceramic particle size of about 2 to 10 μm. To form a high-precision passive element in the passive element forming layer 122 of the high-frequency module 120, the ceramic layer surface has to be flattened by polishing before forming the passive element forming layer 122. Since the ceramic substrate is low in loss but it has a relatively high dielectric constant (8 to 10 of alumina, and 5 to 6 of glass ceramic), the high-frequency module 120 will incur interference between multiple layers of wiring, be lower in reliability and less immune to noises.

FIG. 4 shows a still another conventional high-frequency module. The high-frequency module, generally indicated with a reference 130, uses an organic substrate 132. As shown, this high-frequency module 130 is composed of a base substrate block 131 including the organic substrate 132 and a wiring layer 133 formed on either side of the organic substrate 132 with the printed-circuit board production technique, and an element forming layer 134 in which a capacitor 135, inductor 136 or a resistor (not shown) is formed with the thin-film forming technique. In the high-frequency module 130, an IC chip 137 is mounted in the element forming layer 134 by the flip chip bonding, and there are formed on the wiring layers 133 in the base substrate block 131 a strip line 138 as a distributed parameter circuit having resonator, filter and other functions, a power circuit, bias circuit, etc. which will not be described in detail.

In the high-frequency module 130 shown in FIG. 4, the wiring layers 133 in the base substrate block 131 include first and second wiring layers 133a and 133b formed on the front side of the organic substrate 132, and third and fourth wiring layers 133c and 133d formed on the rear side of the organic substrate 132. As above, in this high-frequency module 130, the strip line 138, power circuit-or bias circuit or the like is formed in the base substrate block 131 and the capacitors 135 and inductor 136 are formed in the element forming layer 134. To form these elements efficiently and avoid interference between them, the first and third wiring layers 133a and 133c are formed each as a grounding layer.

The high-frequency module 130 shown in FIG. 4 is characterized in that use of a relatively low-cost organic substrate 132 can assure to provide a lower-cost high-frequency module and a desired wiring layer 133 can be formed more easily with the printed-circuit board production technique. For example, by flattening the surface of the base substrate block 131 by polishing, a high-precision capacitor 135 and inductor 136 can be formed in the element forming layer 134 of the high-frequency module 130, the base substrate block 131 and element forming layer 134 can be electrically isolated from each other to improve the performance, and a power circuit etc. having a sufficiently large area can be formed to assure a high-regulation power supply.

In the high-frequency module 130 shown in FIG. 4, the capacitor 135 and inductor 136 formed in the element forming layer 134 are influenced by the ground pattern of the first wiring layer 133a in the base substrate block 131. In the high-frequency module 130, the inductor 136 develops a capacitance between itself and the ground pattern to lower the self-resonant frequency and quality factor Q. Also, in the high-frequency module 130, the performances of the capacitor 135 and resistor vary and become worse.

On the other hand, the strip line 138 as the distributed parameter circuit formed in the base substrate block 131 of the high-frequency module 130 in FIG. 4 is influenced by conductor loss as well as by a dielectric loss. The organic substrate 132 is formed to have a high-frequency performance, namely, a low dielectric constant, and a low-loss character due to a low dielectric loss tangent (Tan δ). The organic substrate 132 is formed from an organic material selected from materials including liquid crystal polymer, benzocyclobutene, polyimide, polynorbornen, polyphenylether, polytetrafluoroethylene, BT-resin or each of these resins having ceramic powder dispersed therein. As shown in FIG. 4, the organic substrate 132 is formed from a woven glass fabric 141 and such an organic material 140 provided integrally on the woven glass fabric 141 as a core to have an improved bending strength, rupture strength, etc.

The organic substrate 132 is formed from the woven glass fabric 141 formed by weaving glass fibers 142 with a pitch i into a mesh pattern as shown in detail in FIG. 5 and the organic material 140 provided integrally on the woven glass fabric 141 as a core. The organic substrate 132 is formed in a part of the second wiring layer 133b resonant patterns (copper pattern) 138a and 138b formed from a pair of parallel strip lines and which form together a λ/4 resonator 143. In case the glass fibers are woven with a large pitch i, the resonant patterns 138a and 138b in the resonator 143 are formed over parts indicated with a solid line in FIG. 6 and where no glass fibers 142 are laid as indicated with solid and parts indicated with a dot-dashed line in FIG. 6 and where the glass fibers 142 are laid.

In the organic substrate 132, the effective dielectric constant “varies” because the dielectric loss tangent (Tan δ) varies depending upon whether or not the glass fibers 142 are laid. The “variation” of the effective dielectric constant is found large where the glass fibers 142 are laid thick and small where the glass fibers 142 are laid thin. A relation between this “variation” and amount of the glass fibers 142 is graphically shown in FIG. 7. In FIG. 7, the vertical axis indicates the effective dielectric constant and the horizontal axis indicates a line k-k in FIG. 5. As seen, the effective dielectric constant varies cyclically (with the pitch i) within a range of the difference between the maximum and minimum values thereof It should be noted that the “variation” of effective dielectric constant in a part along the line k-k and where there are laid only vertical glass fibers 142 takes a shape of a simple sine wave but it takes a further complicated shape in a part along the line k-k and where vertical and horizontal glass fibers 142 intersect each other. In the latter case, the “variation” is found large. Thus, the resonator 143 will disadvantageously shows a performance largely variable and difficult to reproduce.

The high-frequency module 130 shown in FIG. 4 is low in reliability and yield because of the variable performance of the resonator 143, due to the performance of the organic substrate 132 formed from the aforementioned glass fibers, and further it is higher in cost because it has to be adjusted after produced. Also, in case the high-frequency module 130 has formed in the base substrate block 131 thereof various passive elements with the thin-film forming technique in addition to the resonator 143 as well as other lines, the same problem takes place due to the variations of the effective dielectric constant and dielectric loss tangent (Tan δ) of the organic substrate formed from the glass fibers.

### DISCLOSURE OF THE INVENTION

Accordingly, the present invention has an object to overcome the above-mentioned drawbacks of the related art by providing a novel high-frequency module and a circuit board for use in the high-frequency module.

The present invention has another object to provide a high-frequency module and a circuit board for use in the high-frequency module, in which the variation in performance of a conductive part thereof is suppressed by reducing the influence of the “variation” of the dielectric constant and dielectric loss tangent (Tan δ), which would be caused by any thick and thin distributions of the glass fibers, to improve the precision and reliability.

The above object can be attained by providing a high-frequency module circuit board in which an organic material is provided integrally on a woven glass fabric, as a core, formed by weaving glass fibers into a mesh pattern and conductive parts forming resonant lines for transmission of a high-frequency signal and passive elements are formed by patterning. In the high-frequency module circuit board, the glass fibers are laid at close intervals of λe/4 (λe: effective wavelength of high-frequency signal) in the wavelength traveling direction of the high-frequency signal in the each of the conductor patterns.

The above high-frequency module circuit board can be produced with a lower cost, and the organic substrate is given a sufficient mechanical strength since an organic material is provided integrally on the woven glass fabric as a core. In the high-frequency module circuit board, since the glass fibers are laid thick in the wavelength traveling direction of a high-frequency signal in the conductor patterns, the glass fibers are generally uniformly distributed in the patterned conductive parts. Thus, the “variation” of the dielectric constant etc., which would be caused by thick and thin distributions of the glass fibers, is reduced. Using the high-frequency module circuit board according to the present invention assures to provide the conductive parts which show stable performances, respectively.

Also, the above object can be attained by providing a high-frequency module including an organic substrate formed from a woven glass fabric, as a core, formed by weaving glass fibers into a mesh pattern and an organic material is provided integrally on the woven glass fabric, and conductor patterns formed on the organic substrate to form resonant lines for transmission of a high-frequency signal and passive elements. According to another aspect of the present invention, there is provided a high-frequency module in which the organic substrate includes the woven glass fabric formed from the glass fibers laid at close intervals of λe/4 (λe: effective wavelength of high-frequency signal) in the wavelength traveling direction of the high-frequency signal.

In the high-frequency module constructed as above, since the glass fibers are laid thick in the wavelength traveling direction of a high-frequency signal in the conductor patterns, the glass fibers are generally uniformly distributed in the conductor patterns on the organic substrate. Thus, the “variations” of the dielectric constant etc., which would be caused by any thick and thin distributions of the glass fibers, is reduced, and the patterned conductive parts show stable performances, respectively. Therefore, according to the present invention, the high-frequency module can be produced with an improved yield and lower cost without the necessity of any post-adjustment treatment.

Also, the above object can be attained by providing a high-frequency module including a base substrate block and a high-frequency circuit block and having formed, by patterning, in the base substrate block and high-frequency circuit block thereof conductive parts forming resonant lines for transmission of a high-frequency signal and passive elements. In this high-frequency module, the base substrate block includes an organic substrate formed from a woven glass fabric formed by weaving glass fibers into a mesh pattern and an organic material provided integrally on the woven glass fabric as a core. On the main side of the organic substrate, there is formed a multilayer wiring layer. At least the top layer of the multilayer wiring layer is flattened to provide a buildup surface. Of the base substrate block, a part thereof opposite to a part of the high-frequency circuit block where the passive elements are formed is used as a non-patterned area. In this non-pattern area, the glass fibers are laid at close intervals of λe/4 (λe: effective wavelength of high-frequency signal) in the wavelength traveling direction of the high-frequency signal. In this high-frequency module, the high-frequency circuit block is formed from a multilayer structure including at least passive elements and wiring patterns provided in a dielectric insulating layer formed on the buildup surface of the base substrate block.

In the above high-frequency module, since the passive elements are provided in the high-frequency circuit block oppositely to the non-patterned part of the base substrate block, the influence of the pattern in the base substrate block on the passive elements is reduced and thus the passive elements will show stable performances, respectively. Further, in the high-frequency module according to the present invention, since the glass fibers are laid at close intervals in the wavelength traveling direction of a high-frequency signal in the conductor patterns on the organic substrate, the glass fibers are distributed generally uniformly in each of the conductor patterns. Thus, the “variations” of the dielectric constant, which would be caused by any thick and thin distributions of the glass fibers, can be reduced. Therefore, the conductor patterns can show stable performances, respectively, and the high-frequency module can be produced with an improved yield and at a lower cost without the necessity of any post-adjustment treatment.

These objects and other objects, features and advantages of the present invention will become more apparent from the following detailed description of the best mode for carrying out the present invention when taken in conjunction with the accompanying drawings.

### BRIEF DESCRIPTION OF THE DRAWINGS

FIGS. 1A and 1B show together an inductor formed in the conventional high-frequency module, in which FIG. 1A is a perspective view of the inductor and FIG. 1B is a sectional view of the inductor.

FIG. 2 is an axial sectional view of the substantial part of a high-frequency module using a conventional silicon substrate.

FIG. 3 is an axial sectional view of the substantial part of a high-frequency module using a conventional glass substrate.

FIG. 4 is an axial sectional view of the substantial part of a high-frequency module in which a copper-clad organic substrate using a glass woven fabric as a core is used as a base substrate block and a high-frequency circuit block having film-shaped passive elements formed thereon is laminated on the base substrate block.

FIG. 5 is a plan view of an organic substrate whose core is a glass woven fabric formed by weaving glass fibers with a pitch i into a mesh pattern, and a resonator conductor pattern of a resonator formed, by patterning, on the organic substrate.

FIG. 6 is also a plan view showing a variation in amount of the glass fibers in some places on the resonator conductor pattern of the resonator.

FIG. 7 graphically illustrates a variation in effective dielectric constant of the organic substrate depending upon an amount of glass fibers.

FIG. 8 is an axial sectional view of the substantial part of a high-frequency module according to the present invention.

FIG. 9 is a plan view of an organic substrate whose core is using, as a core, a glass woven fabric formed by weaving glass fibers with a pitch p into a mesh pattern, and a resonator conductor pattern of a resonator formed, by patterning, on the organic substrate.

FIG. 10 is a plan view of an organic substrate using, as a core, a glass woven fabric formed by weaving glass fibers into a mesh pattern whose mesh obliquity is about 10 deg., and a resonator conductor pattern of a resonator formed, by patterning, on the organic substrate.

FIG. 11 is a plan view of an organic substrate using, as a core, a glass woven fabric formed by weaving glass fibers into a mesh pattern whose mesh obliquity is about 30 deg., and a resonator conductor pattern of a resonator formed, by patterning, on the organic substrate.

FIG. 12 is a plan view of an organic substrate using, as a core, a glass woven fabric formed by weaving glass fibers into a mesh pattern whose mesh obliquity is about 45 deg., and a resonator conductor pattern of a resonator formed, by patterning, on the organic substrate.

FIG. 13 is an axial sectional view of an application of the present invention to a high-frequency module produced by an ordinary method.

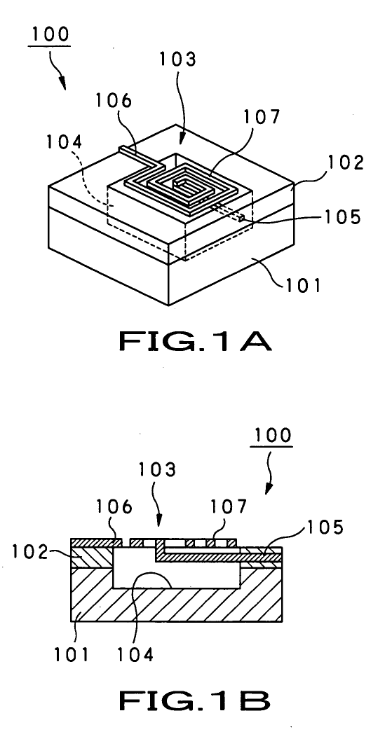

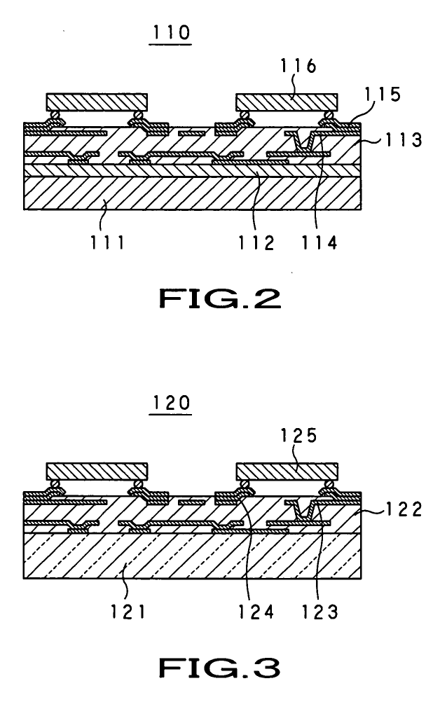

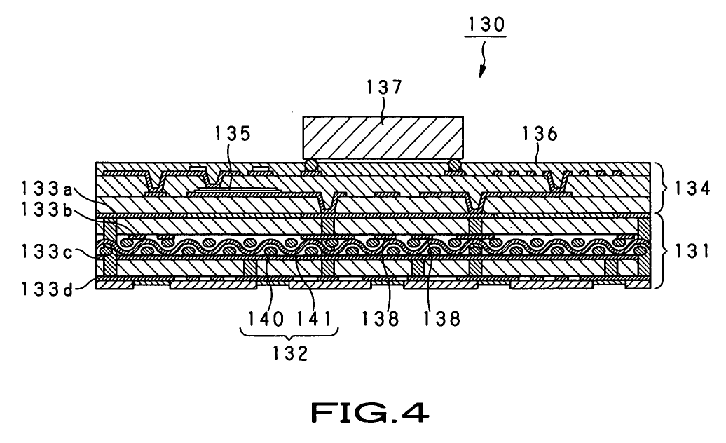

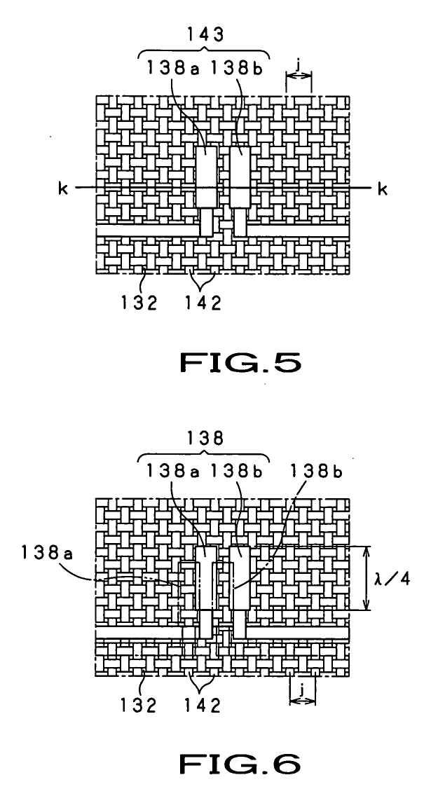

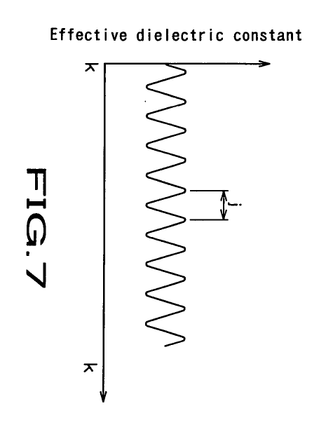

### BEST MODE FOR CARRYING OUT THE INVENTION

The present invention will be described concerning embodiments thereof with reference to the accompanying drawings.

The high-frequency module according to the present invention has an information communication function, information storage function, etc. and it is used as an ultra-small communication module or the like fixedly installed, or removably installed as an option, in an electronic apparatus such as a personal computer, mobile phone, portable digital assistant or a portable audio device. Especially, the high-frequency module according to the present invention is used in an appropriate small-scale radio communication system whose carry frequency is in a band of 5 GHz, for example.

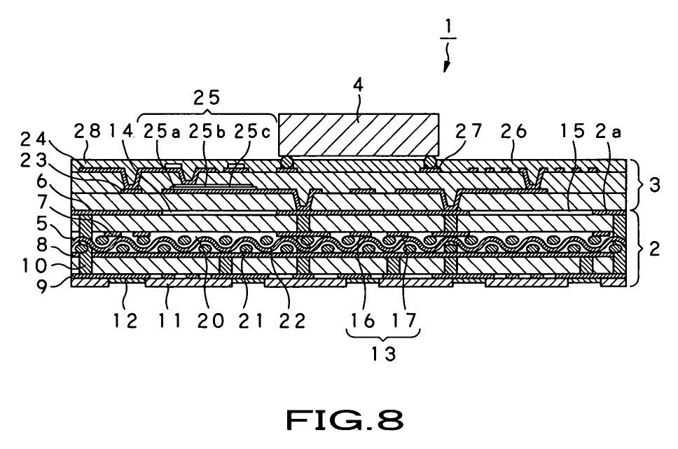

As shown in FIG. 8, the high-frequency module, generally indicated with a reference 1, includes a base substrate block 2, and a high-frequency circuit block 3 formed by lamination on the base substrate block 2. The high-frequency circuit block 3 has mounted on the surface thereof an IC chip 4 having a peripheral circuit function of the high-frequency circuit block 3, and the like. In the high-frequency module 1, the base substrate block 2 has formed therein a power circuit for the high-frequency circuit block 3 and a circuit block for a control system, and is to be mounted on an interposer circuit board or the like (not shown). In the high-frequency module 1, the base substrate block 2 and high-frequency circuit block 3 are electrically isolated from each other, so that the electrical interference with the high-frequency is suppressed for an improved performance. Also, in the high-frequency module 1, a power circuit and grounding circuit, having a sufficient area, are formed in the base substrate block 2 to assure a high-regulation power supply to the high-frequency circuit block 3.

As shown in FIG. 8, in the base substrate block 2, there is provided an organic substrate 5 formed from a both-side copper clad laminate as a core member and dielectric insulative layers and wiring layers are formed in a multilayer structure on either side of the organic substrate 5 with the conventional printed-circuit board production technique or the like. The base substrate block 2 consists of four layers including a first wiring layer 6 and second wiring layer 7 provided at one side thereof and a third wiring layer 8 and fourth wiring layer 9 provided at the other side, with the organic substrate 5 being laid between the first and second wiring layers 6 and 7 and the third and fourth wiring layers 8 and 9. In the base substrate block 2, the first and fourth wiring layers 6 and 9 are interlayer-connected to each other through via holes 10 appropriately formed.

In the base substrate block 2, the aforementioned second and third wiring layers 7 and 8 are formed on a both-side copper-clad organic substrate 5, for example, by forming wiring patterns and element patterns appropriately by photolithography and etching of a copper foil provided on either side, front and rear, of the organic substrate 5 and by forming thin layers of passive elements (not shown) as necessary. Also, in the base substrate block 2, the aforementioned first and fourth wiring layers 6 and 9 are formed on the both-side copper-clad organic substrate 5 by bonding a resinified copper foil on either side, front and rear, of the organic substrate 5 after forming the second and third wiring layers 7 and 8, forming wiring patterns and element patterns appropriately by photolithography and etching of each copper foil and by forming thin layers of passive elements (not shown) as necessary as above.

The base substrate block 2 has the fourth wiring layer 9 thereof covered with a protective layer 11 made of a solder resists or the like. Openings are formed in predetermined places in the protective layer 11 by photolithography or the like. The base substrate block 2 has a terminal formed 12 by electroless plating of Ni—Au, for example, on an appropriate wiring pattern of the fourth wiring layer 9, exposed in each opening in the protective layer 11. It should be noted that when the high-frequency module 1 is mounted on an interposer circuit board (not shown), it is connected at each of the terminals 12 of the base substrate block 2 to the interposer circuit board.

In the base substrate block 2, the first and third wiring layers 6 and 8 are used as grounds to shield the inner circuits. Also on the second wiring layer 7 between the first and third wiring layers 6 and 8 in the base substrate block 2, there is formed, by patterning, a distributed parameter circuit, for example, a resonator 13, as strip lines as will be described in detail later. In the base substrate block 2, the third wiring layer 8 is formed as an all-overlaying pattern over the organic substrate 5, and pattern openings 14 and 15 are formed in positions opposite to a capacitor 25 and inductor 26, which will be described in detail later, formed in the high-frequency circuit block 3 on the first wiring layer 6 by thin-film forming.

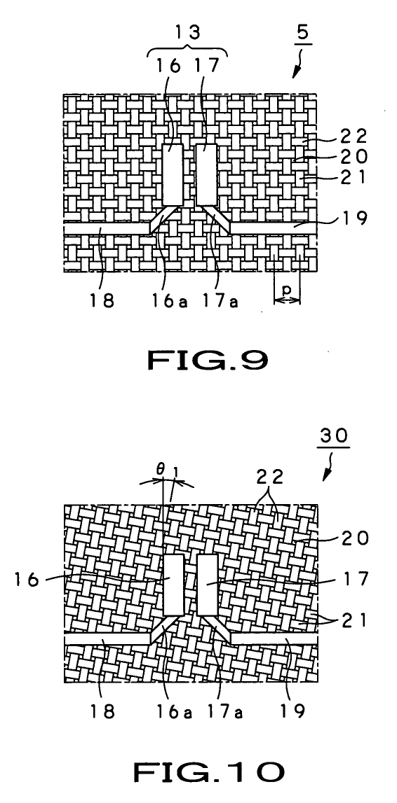

As shown in FIG. 9, the resonator 13 includes a pair of mutually parallel resonator conductor patterns 16 and 17 formed, by the distributed parameter designing, to have an electric length of about λ/4 of the 5-GHz carrier frequency band, that is, a length m of about 6 mm, and input and output patterns 18 and 19 extended like an arm toward laterally by lead patterns 16a and 17a, respectively, each formed at one end of each of the resonator conductor patterns 16 and 17. In the resonator 13, the first resonator conductor pattern 16 forms an input terminal while the second resonator pattern 17 forms an output terminal. To prevent radio waves from being reflected, the lead patterns 16a and 17a are electrically connected, at an angle of about 45 deg., to the resonator conductor pattern 16 and input pattern 18 and to the resonator conductor pattern 17 and output pattern 19, respectively. In the resonator 13, the resonator conductor patterns 16 and 17 are short-circuited at one end thereof to the ground through via holes 10 and open-circuited at the other end, which will not be described in detail.

The resonator 13 included in the high-frequency module 1 according to the present invention has a so-called tri-plate structure in which the resonator conductor patterns 16 and 17 are formed as a strip line structure in the base substrate block 2. The resonator 13 forms an equivalent circuit in which parallel resonance circuits are capacitive-coupled to each other via an dielectric insulating layer. The resonator 13 is characterized in that the field intensity varies depending upon the distance between the resonator conductor patterns 16 and 17 in the odd mode of excitation while varying depending upon the thickness of the dielectric insulating layer in the even mode of excitation. In the resonator 13, the field strength varies as above in the odd and even modes of excitation and the degree of coupling between the resonator conductor patterns 16 and 17 varies correspondingly, resulting in a performance variation. Therefore, the base substrate block 2 is constructed for the dielectric insulating layer to suppress the performance variation of the resonator 13.

The base substrate block 2 uses the organic substrate 5 which is low in dielectric constant and dielectric loss tangent (Tan δ), that is, superior in high-frequency performance, and excellent in mechanical rigidity, thermal resistance and chemical resistance. The organic substrate 5 includes the organic material 20 provided integrally on the woven glass fabric 21, as a core, formed by weaving the glass fibers 22 into a mesh pattern, and the copper foil attached on either side of the woven glass fabric 21. The organic material 20 is formed from an organic material selected from materials including liquid crystal polymer (LCP), benzocyclobutene (BCB), polyimide, polynorbornen (PNB), polyphenylether (PPE), polytetrafluoroethylene (“teflon” as registered trademark), Wavelength of high or each of these resins having an inorganic material such as ceramic powder dispersed therein.

As shown in FIG. 9, the woven glass fabric 21 is formed by weaving the glass fibers 22 each having a predetermined diameter with a pitch p into a mesh pattern. The organic substrate 5 has an equivalent dielectric constant se which depends upon the performances of the aforementioned organic material 20 and woven glass fabric 21. The organic substrate 5 has a dielectric constant which is influenced by the glass fibers 22 woven in the mesh pattern as above. That is, the dielectric constant of the organic substrate 5 varies depending upon the dielectric constant of the glass fibers 22 where the latter are provided but upon that of the organic material 20 where the glass fibers 22 are not provided. In the organic substrate 5, the resonator 13 formed in the first wiring layer 6 will have the performance thereof varied for a difference in dielectric constant between the organic material 20 and glass fibers 22. Namely, the organic substrate 5 is constructed for the resonator 13 not to be influenced by the variation of the dielectric constant.

That is, the organic substrate 5 includes, as a core, the woven glass fabric 21 formed by weaving the glass fibers with the pitch p in the mesh pattern. The pitch p of the mesh pattern of the woven glass fibers 22 is smaller than the effective wavelength (λe), in the wavelength traveling direction, of a high-frequency signal (f) used in the high-frequency module 1 and traveling through the organic substrate 5. The effective wavelength of the high-frequency signal is simply expressed by λe=√εe×f. In the organic substrate 5 using the woven glass fabric 21, the glass fibers 22 are distributed at close intervals of λe/4 in resonator conductor patterns 16 and 17 of the resonator 13 formed over a length of λe/4 as shown in FIG. 9 and an area between the resonator conductor patterns 16 and 17.

Therefore, the organic substrate 5 is formed with the glass fibers 22 distributed generally evenly, neither thick nor thin, in relation to the resonator conductor patterns 16 and 17 of the resonator 13. Since the conductor patterns 16 and 17 are formed in the dielectric insulating layer of the organic substrate 5 in which the dielectric constant εe is uniformed, so the dielectric constant εe varies less in the resonator 13 which will thus show a stable performance. It should be noted that in case the resonator 13 uses the organic substrate 5 in which the pitch p of the mesh pattern of the woven glass fibers 22 is smaller than λe/10, the glass fibers 22 are not uniformly distributed in the conductor patterns 16 and 17 of the resonator 13 and in the area between the conductor patterns 16 and 17. Namely, the glass fibers 33 are provided in some places but not in other places. The resonator 13 will have the performance thereof degraded under the influence of a large variation in dielectric constant se between the places with the glass fibers 22 and those without the glass fibers 22.

In the base substrate block 2, an insulating rein layer is formed on the first wiring layer 6. The insulating resin layer is flattened, and a buildup surface 2a is formed on the insulating resin layer. The high-frequency circuit block 3 is formed on the buildup surface 2a. At this time, the insulating resin layer is flattened by polishing. More specifically, the insulating resin layer is polished with an abrasive prepared from a mixture of alumina and silica, for example, until the wiring pattern of the first wiring layer 6 is exposed. The flattened buildup surface 2a of the base substrate block 2 may be formed not only by the above-mentioned polishing but by the reactive ion etching (RIE), plasma etching (PE) or the like.

Note that the base substrate block 2 may have multiple wiring layers and passive elements appropriately formed only on one side of the organic substrate 5 with a dielectric insulating layer laid between them. Also, it is of course that the wiring layers formed on the base substrate block 2 are not limited to the four wiring layers 6 to 9, first to fourth, but it may have more wiring layers formed therein. Further, the base substrate block 2 may be formed by joining both-side copper clad organic substrates to each other with a prepreg provided between them. The base substrate block 2 may be formed by any other appropriate method. In the base substrate block 2 using an organic substrate including a plurality of woven glass fabrics, there should be used, as a core, a woven glass fabric formed by weaving glass fibers in a pitch p only for the organic substrate in which the resonator 13, strip line or passive element is formed.

In the base substrate block 2, the dielectric insulating layer may be formed on either main side, front and rear, of the organic substrate 5 with the second and third wiring layers 7 and 8 having been formed, and then the first and four wiring layers 6 and 9 be formed in the dielectric insulating layer. In this case, a dielectric insulating material is applied to the main side of the organic substrate 5 by spin coating or dipping to form the dielectric insulating layer, and then predetermined pattern recesses for the first and four wiring layers 6 and 9 are formed in this dielectric insulating layer by an appropriate method. The base substrate block 2 may have a conductor layer formed over the dielectric insulating layer by sputtering or the like method, and the dielectric insulating layer and conductor layer in the pattern recesses be flattened by chemical polishing to form the buildup surface 2a.

The high-frequency module 1 according to the present invention has the high-frequency circuit block 3 formed by lamination on the buildup surface 2a of the aforementioned base substrate block 2. The high-frequency module 1 is higher in precision and easier to mass-produce with less costs since the first to fourth wiring layers 6 to 9 are formed on the less expensive organic substrate 5 or the like with the conventional printed-circuit board production technique.

On the buildup surface 2a of the base substrate block 2 formed as above, there are formed, by lamination, the high-frequency circuit block 3 formed from first and second wiring layers 23 and 24 as shown in FIG. 8. The first and second wiring layers 23 and 24 of the high-frequency circuit block 3 are connected to each other and appropriately to the wiring layers on the base substrate block 2 through the via holes 10. The wiring layer 23 of the high-frequency circuit block 3 is formed from the dielectric insulating layer and an appropriate conductor pattern. The dielectric insulating layer is formed on the buildup surface 2a of the base substrate block 2 by applying a similar dielectric insulating material to the aforementioned organic material 20 to a predetermined thickness to the buildup surface 2a by spin coating or roll coating. The dielectric insulating layer has a thin metal layer of Al, Pt or Au, for example, formed the surface thereof by sputtering, and the conductor pattern is formed on the thin metal layer by photolithography and etching.

The dielectric insulating layer has a tantalum nitride layer formed over the surface thereof including the conductor pattern by sputtering, for example. The tantalum nitride layer acts as a resistive element in the first wiring layer 23 and it is anodized to provide a base of tantalum oxide which will act as a dielectric layer 25b of a capacitor 25. An anodization masking layer having openings formed in portions thereof opposite to an lower electrode 25a of the capacitor 25 and to a portion where the resistor is to be formed is formed on the tantalum nitride layer and it is anodized. In the tantalum nitride layer, the portions corresponding to the openings are selectively anodized to provide the tantalum oxide layer and unnecessary portions are removed by etching or the like treatment. It should be noted that the method of forming the capacitor 25 and resistor in the high-frequency circuit block 3 is not limited to the above one but the whole surface of the tantalum nitride layer may be anodized to provide a tantalum oxide layer and then the tantalum oxide layer thus formed be patterned, for example.

Also, the second wiring layer 24 is formed from a dielectric insulating layer and conductor pattern, formed similarly to the dielectric insulating layer and conductor pattern in the aforementioned first wiring layer 23. For example, a Cu layer, whose loss in a high-frequency band is small, is formed, by film forming, on the dielectric insulating layer by sputtering or the like, and a conductor pattern is formed on the Cu later by photolithography and etching. Further, on the second wiring layer 24, there are formed an upper electrode 25c formed on a dielectric insulating layer 25b and which forms, together with the lower electrode 25a of the first wiring layer 23, the capacitor 25, and an inductor 26 formed from a spiral pattern for example, as shown in FIG. 8. The second wiring layer 24 has an appropriate terminal 27 to which the IC chip 4 and the like are to be mounted by flip-chip bonding. The terminal 27 of the second wiring layer 24 is exposed to outside, and the second wiring layer 24 itself is entirely covered with a protective layer 28 of solder resist, for example.

Since the high-frequency circuit block 3 constructed as above is formed, by lamination, on the flat buildup surface 2a of the base substrate block 2, passive elements such as the high-precision capacitor 25 and inductor 26, etc. are formed, by lamination, on the high-frequency circuit block 3. The high-frequency circuit block 3 is electrically isolated from the base substrate block 2 where the power circuit etc. are formed, and thus it has an improved performance since the electrical interference is suppressed. In the high-frequency circuit block 3, the capacitor 25 and inductor 26 are formed opposite to the pattern openings 14 and 15 in the first wiring layer 6 working as the ground of the base substrate block 2. Therefore, the high-frequency circuit block 3 will hold a predetermined performance since a capacitance developed between the capacitor 25 etc. and ground pattern will not cause the self-resonant frequency and quality factor Q value to be degraded. It should be noted that the high-frequency circuit block 3 is covered with a shield cover which shields the electromagnetic wave noise, as necessary.

The aforementioned high-frequency module 1 according to the present invention uses the organic substrate 5 whose core is the woven glass fabric 21 formed by weaving the glass fibers 22 into a mesh pattern whose pitch p is λe/10 or less in the wavelength traveling direction of a high-frequency signal. However, the present invention is not limited to the organic substrate 5 but it is applicable to organic substrates 30 to 32 whose core is the woven glass fabric 21 in which the mesh of glass fibers 22 is inclined in relation to the conductor patterns 16 and 17 of the resonator 13 in the wavelength traveling direction of a high-frequency signal as shown in FIGS. 10 to 12.

Basically similar to the organic substrate 5, each of the organic substrates 30 to 32 shown in FIGS. 9 to 12, respectively, uses the woven glass fabric 21 formed by weaving the glass fibers 22 into a mesh pattern and on which the organic material 20 is provided integrally on the woven glass fabric 21 as a core. In each of the organic substrates 30 to 32, the mesh pitch of the glass fibers 22 is not limited to the aforementioned value p<λe/10. For example, the organic substrate may use a woven glass fabric 21 formed by weaving the glass fibers in a similar pitch to that in the conventional organic substrate. It should be noted that the same or similar elements of the organic substrates 30 to 32 as or to those in the aforementioned organic substrate 5 will be indicated with the same or similar references as or to those used in explanation of the organic substrate 5 and will not be described in detail. Of course, the mesh pitch of the glass fibers 22 in each of the organic substrates 30 to 62 may be less than λe/10.

The organic substrate 30.shown in FIG. 10 uses the woven glass fabric 21 in which the resonator conductor patterns 16 and 17 of the resonator 13 are formed, by patterning, at an angle of inclination θ₁ of about 10 deg. in relation to the mesh of the glass fibers 22. That is, in the organic substrate 30, the mesh of the glass fibers 22 is inclined at the angle θ₁ of about 10 deg. in relation to the wavelength traveling direction of a high-frequency signal as indicated with an arrow in FIG. 10. In the organic substrate 30, the resonator conductor patterns 16 and 17 are formed with reference to a baseline (not shown) parallel to the perimeter of the organic substrate 30. The organic substrate 30 is formed from the woven glass fabric 21 in which the mesh direction of the glass fibers 22 is inclined about 10 deg. in relation to the baseline and on which the organic material 20 is integrally provided.

Therefore, in the organic substrate 30 shown in FIG. 10, even if the mesh pitch of the glass fibers 22 is slightly large, a substantially large number of glass fibers 22 cross the resonator conductor patterns 16 and 17 and thus the glass fibers 22 are laid generally uniformly. Namely, the glass fibers 22 are either distributed thick in some areas nor thin other areas. Lead patterns 16a and 17a are electrically connected, at an angle of about 45 deg. as previously described, to the resonator conductor patterns 16 and 17. The glass fibers 22 will be generally uniformly distributed on the lead patterns 16a and 17a and also on the input pattern 18 and output pattern 19. Since the “variations” of the dielectric constant etc. of each resonator conductor patterns 16 and 17 are reduced, so the resonator 13 in the organic substrate 30 will show a stable performance.

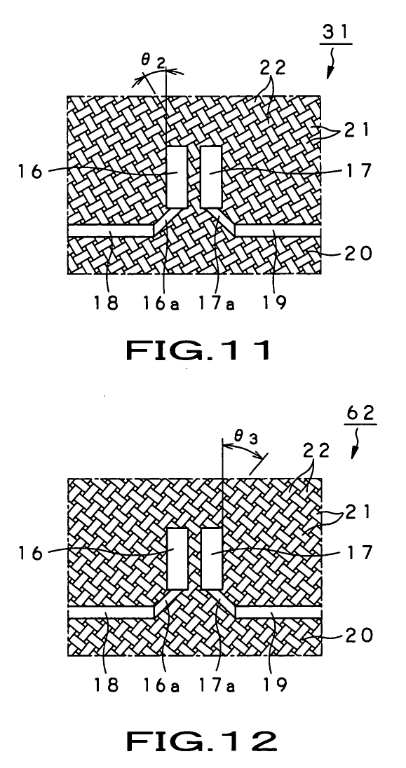

The organic substrate 31 shown in FIG. 11 uses the woven glass fabric 21 in which the resonator conductor patterns 16 and 17 of the resonator 13 are formed, by patterning, at an angle of inclination θ₂ of about 30 deg. in relation to the mesh of the glass fibers 22. Also in the organic substrate 31, the mesh of the glass fibers 22 is inclined about 30 deg. in relation to the baseline and on which the organic material 20 is integrally provided. Therefore, even if the mesh pitch of the glass fibers 22 is somewhat large, a larger number of glass fibers 22 that the number of glass fibers in the organic substrate 30 in which the glass fiber mesh is inclined 10 deg. cross the resonator conductor patterns 16 and 17 and thus the glass fibers 22 are laid generally uniformly. Namely, the glass fibers 22 are either distributed thick in some areas nor thin other areas. Since the “variations” of the dielectric constant etc. of each resonator conductor patterns 16 and 17 are reduced, so the resonator 13 in the organic substrate 31 will show a stable performance.

The organic substrate 62 shown in FIG. 12 uses the woven glass fabric 21 in which the resonator conductor patterns 16 and 17 of the resonator 13 are formed, by patterning, at an angle of inclination θ₃ of about 45 deg. in relation to the mesh of the glass fibers 22. Also in the organic substrate 62, the mesh of the glass fibers 22 is inclined about 45 deg. in relation to the baseline and on which the organic material 20 is integrally provided. Therefore, even if the mesh pitch of the glass fibers 22 is somewhat large, a larger number of glass fibers 22, than that in the organic substrate 30 in which the glass fiber mesh is inclined 10 deg. as shown in FIG. 10 and that in the organic substrate 31 in which the glass fiber mesh is inclined 30 deg. as shown in FIG. 11, cross the resonator conductor patterns 16 and 17 and thus the glass fibers 22 are laid generally uniformly. Namely, the glass fibers 22 are either distributed thick in some areas nor thin other areas. Since the “variations” of the dielectric constant etc. of each resonator conductor patterns 16 and 17 are reduced, so the resonator 13 in the organic substrate 62 shown in FIG. 12 will show a stable performance.

Note that in the organic substrates used in the circuit board according to the present invention, in case the woven glass fabric 21 has the mesh of the glass fibers 22 inclined about 10 deg. or less in relation to the baseline in the wavelength traveling direction of a high-frequency signal and at an angle between 80 deg. and 90 deg. in a symmetrical relation and it has the organic material 20 provided integrally thereon, slightly less glass fibers cross the resonator conductor patterns 16 and 17, so that the “variations” of the dielectric constant etc. cannot be positively suppressed. In this case, the resonator 13 will not show any stable performance.

In the aforementioned high-frequency module 1 according to the present invention, the resonator 13 is formed in the base substrate block 2 while a capacitor 32, inductor 33 prersistor is formed in the high-frequency circuit block 3. However, the present invention is not limited to this construction. In the high-frequency module 1 according to the present invention, a strip line and passive elements may be formed in the base substrate block 2. Also in this case, the glass fibers 22 of the woven glass fabric 21 may be distributed generally uniformly at close intervals of λ/4 in each conductor pattern.

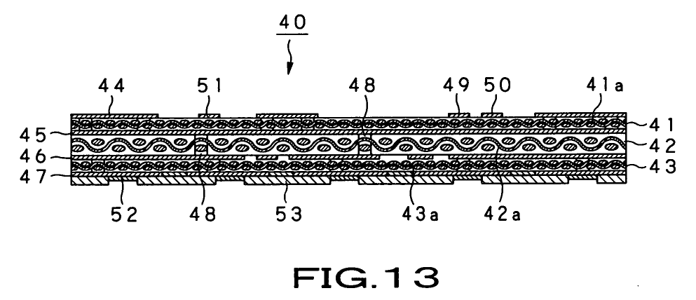

In the aforementioned high-frequency module I, a multilayer organic substrate is used as the base substrate block 2 and various passive elements are formed, by film forming, on the flattened buildup surface 2a of the base substrate block 2 to provide the high-frequency circuit block 3. However, the present invention is not limited to such a high-frequency module 1 but it is applicable to a high-frequency module 40 formed by integrally laminating first to third organic substrates 41 to 43, each formed from an organic substrate including a woven glass fabric, with a prepreg provided between them as shown in FIG. 13, for example. The first to third organic substrates 41 to 43 are formed from woven glass fabrics 41a to 43a, each formed by weaving glass fibers into a mesh pattern and on which an organic material is integrally provided, similarly to the organic substrate 5 in the aforementioned high-frequency module 1.

As shown in FIG. 13, the high-frequency module 40 has a first wiring layer 44 and second wiring layer 45 formed on main sides, front and rear, respectively, of the first organic substrate 41 formed from a both-side copper clad substrate, and a third wiring layer 46 and fourth wiring layer 47 formed on main sides, front and rear, respectively, of the third organic substrate 43 formed from a both-side copper clad substrate, with the second organic substrate 42 interposed between the first and third organic substrates 41 and 43. It should be noted that in the high-frequency module 40, for example, the first organic substrate 41 may be formed from a both-side copper clad substrate while the second and third organic substrates 42 and 43 may be formed from a single-side copper clad substrate.

In the high-frequency module 40 shown in FIG. 13, the first to fourth wiring layers 44 to 47 are formed each from a predetermined conductor pattern by photolithography and etching of a copper foil attached on the organic substrate. In this high-frequency module 40, the-appropriate conductor patterns of the first to fourth wiring layers 44 to 47 are connected appropriately to each other through via holes 48. The uppermost first wiring layer 44 provides a first ground layer and has a pair of resonator conductor patterns 49 and 50 having a length of λ/4 and parallel to each other (namely, a micro strip line structure), micro strip line 51, etc. The second wiring layer 45 is formed from a so-called solid patter and provides a second ground layer.

In the above high-frequency module 40, for example, the third wiring layer 46 has a conductor pattern forming a power circuit and control system signal circuit, and the fourth wiring layer 47 has a conductor pattern forming a power circuit. In this high-frequency module 40, the fourth wiring layer 47 is covered with a protective layer 52 and has an opening formed therein by photolithography of the protective layer at a predetermined place. Further in the high-frequency module 40, terminals 53 plated with solderless Ni—Au for example are formed on an appropriate wiring pattern, exposed at each opening, of the fourth wiring layer 47. This high-frequency module 40 is mounted on an interposer (not shown) with the input and output terminals 53 laid between them.

In the high-frequency module 40, the dielectric constant of the first organic substrate 41 will have an influence on the resonator conductor patterns 49 and 50 and micro strip line 51, formed especially on the first wiring layer 44.

In the high-frequency module 40 shown in FIG. 13, the resonator conductor patterns 49 and 50 and micro strip line 51 are influenced by a variation of the dielectric constant as in the high-frequency module 1 shown in FIG. 8 if the glass fibers are distributed thick in some areas and thin in other areas in the woven glass fabric 41a of the first organic substrate 41.

In the high-frequency module 40 shown in FIG. 13, the glass fibers in the woven glass fabric 41a of the first organic substrate 41 are distributed at close intervals of λe/4 (λe: effective wavelength of high-frequency signal) in the wavelength traveling direction of a high-frequency signal in an area where at least the resonator conductor patterns 49 and 50 and micro strip line 51 are formed. In the first organic substrate 41, the woven glass fabric 41a is formed as a core by weaving the glass fibers with a pitch of less than λe/10 in the wavelength traveling direction of a high-frequency signal whose frequency is f. The first organic substrate 41 uses, as a core, the woven glass fabric 41a formed by weaving the glass fibers with the mesh thereof inclined at an angle of 10 deg. or more in relation to the resonator conductor patterns 49 and 50 and micro strip line 51.

In the high-frequency module 40 constructed as above according to the present invention, since the glass fibers are distributed generally uniformly on the resonator conductor patterns 49 and 50 and micro strip line 51, the “variations” of the dielectric constant etc. of the first organic substrate 41 are suppressed, so that the resonator and line will show stable performance.

Note that since the second to fourth wiring layers 45 to 47 in the high-frequency module 40 shown in FIG. 13 is not influenced by any high frequency, the second and third organic substrates 42 and 43 can be formed from organic substrates whose cores are woven glass fabrics 42a and 43a, respectively, having an ordinary structure.

In the foregoing, the present invention has been described in detail concerning certain preferred embodiments thereof as examples with reference to the accompanying drawings. However, it should be understood by those ordinarily skilled in the art that the present invention is not limited to the embodiments but can be modified in various manners, constructed alternatively or embodied in various other forms without departing from the scope and spirit thereof as set forth and defined in the appended claims.

Industrial Applicability

As having been described in the foregoing, the high-frequency module according to the present invention uses a circuit board including a woven glass fabric formed by weaving glass fibers into a mesh pattern and an organic material provided integrally on the woven glass fiber as a core, the woven glass fabric having the glass fibers distributed at close intervals of λe/4 (λe: effective wavelength of high-frequency signal) in the wavelength traveling direction of the high-frequency signal in the conductor patterns in which resonant lines for transmission of the high-frequency signal and passive elements are formed. Use of the woven glass fabric as the core assures to hold a sufficient mechanical strength for the organic substrate, and generally uniform distribution of the glass fibers in the conductor patterns assures to reduce the “variations” of the dielectric constant etc. of the organic substrate, which would be caused by any thick and thin distributions of the glass fibers. Thus, the conductors can be patterned to show a stable performance.

Since in the above high-frequency module circuit board, the glass fibers are laid thick in the wavelength traveling direction of a high-frequency signal in the conductor patterns of the organic substrate, they are distributed generally uniformly in each of the conductor patterns and thus the “variations” of the dielectric constant etc. of the organic substrate, which would be caused by thick and thin distributions of the glass fibers, can be reduced and it is possible to provide conductor patterns which show a stable performance. The high-frequency module circuit board can thus be produced with an improved yield and hence at a lower cost without the necessity of any post-adjustment steps of processing.

The high-frequency module according to the present invention includes a base substrate block and high-frequency circuit block, and has conductor patterns formed in the base substrate block and high-frequency circuit block and on which resonant lines for transmission of the high-frequency signal and passive elements are formed. The base substrate block includes an organic substrate formed from a woven glass fabric formed by weaving glass fibers into a mesh pattern and an organic material provided integrally on the woven glass fabric as a core. On the main side of the organic substrate, there is formed a multilayer wiring layer. At least the top layer of the multilayer wiring structure is flattened to provide a buildup surface. Of the base substrate block, a part thereof opposite to a part of the high-frequency circuit block where the passive elements are formed is used as a non-patterned area. In this non-pattern area, the glass fibers are laid at close intervals of λe/4 (λe: effective wavelength of high-frequency signal) in the wavelength traveling direction of the high-frequency signal.

In the above high-frequency module, since the passive elements are provided in the high-frequency circuit block oppositely to the non-patterned part of the base substrate block, the influence of the pattern in the base substrate block is reduced and thus the passive elements will show stable performances, respectively. Further, in the high-frequency module according to the present invention, since the glass fibers are laid at close intervals in the wavelength traveling direction of a high-frequency signal in the conductor patterns on the organic substrate, the glass fibers are distributed generally uniformly in each of the conductor patterns. Thus, the “variations” of the dielectric constant, which would be caused by any thick and thin distributions of the glass fibers, can be reduced. Therefore, the conductor patterns can show stable performances, respectively, and the high-frequency module can be produced with an improved yield and at a lower cost without the necessity of any post-adjustment treatment.

1. A circuit board for use in a high-frequency module, in which an organic material is provided integrally on a woven glass fabric, as a core, formed by weaving glass fibers into a mesh pattern and conductive parts forming resonant lines for transmission of a high-frequency signal having a frequency (f) and passive elements are formed by patterning,
the woven glass fabric being formed from the glass fibers laid at close intervals of λe/4 (λe: effective wavelength of high-frequency signal) in the wavelength traveling direction of the high-frequency signal in the each of the conductor pattern areas.

2. The circuit board as set forth in claim 1, wherein the woven glass fabric is formed by warding the glass fibers into a mesh pattern whose pitch is smaller than λe/10 (λe: effective wavelength of high-frequency signal).

3. The circuit board as set forth in claim 1, wherein the woven glass fabric is formed from the glass fibers woven in a mesh pattern inclined at an angle between 10 and 80 deg. in the wavelength traveling direction of the high-frequency signal.

4. The circuit board as set forth in claim 1, wherein the organic substrate is formed from an organic material selected from materials including liquid crystal polymer, benzocyclobutene, polyimide, polynorbornen, polyphenylether, polytetrafluoroethylene, BT-resin, which is low in dielectric constant and low in loss, or each of these resins having ceramic powder dispersed therein.

5. A high-frequency module including an organic substrate formed from a woven glass fabric, as a core, formed by weaving glass fibers into a mesh pattern and an organic material is provided integrally on the woven glass fabric, and conductor patterns formed on the organic substrate to form resonant lines for transmission of a high-frequency signal and passive elements,
the organic substrate including the woven glass fabric formed from the glass fibers laid at close intervals of λe/4 (λe: effective wavelength of high-frequency signal) in the wavelength traveling direction of the high-frequency signal in the patterned conductor areas.

6. The high-frequency module as set forth in claim 5,wherein the woven glass fabric is formed by warding the glass fibers into a mesh pattern whose pitch is smaller than λe/10 (λe: effective wavelength of high-frequency signal).

7. The high-frequency module as set forth in claim 5, wherein the woven glass fabric is formed from the glass fibers woven in a mesh pattern inclined at an angle between 10 and 80 deg. in the wavelength traveling direction of the high-frequency signal.

8. The high-frequency module as set forth in claim 5, wherein the organic substrate is formed from an organic material selected from materials including liquid crystal polymer, benzocyclobutene, polyimide, polynorbornen, polyphenylether, polytetrafluoroethylene, BT-resin, which is low in dielectric constant and low in loss, or each of these resins having ceramic powder dispersed therein and provided integrally on the woven glass fabric as a core.

9. The high-frequency module as set forth in claim 5, wherein the organic substrate is a multilayer wiring structure in which multiple wiring layers are formed.

10. A high-frequency module comprising:
a base substrate block including an organic substrate formed from a woven glass fabric formed by weaving glass fibers into a mesh pattern and an organic material provided integrally on the woven glass fabric as a core, a multilayer wiring layer being formed on the main side of the organic substrate and at least the top layer of the multilayer wiring layer being flattened to provide a buildup surface; and
a high-frequency circuit block formed, as a multilayer structure including at least passive elements and wiring patterns, in a dielectric insulating layer formed on the buildup surface of the base substrate block;
conductor patterns which provide resonant lines for transmission of the high-frequency signal and passive elements being formed in the base substrate block and high-frequency circuit block; and
of the base substrate block, a part thereof opposite to a part of the high-frequency circuit block where the passive elements are formed, being used as a non-patterned area and the glass fibers in the woven glass fabric in the non-patterned area being laid at close intervals of λe/4 (λe: effective wavelength of high-frequency signal) in the wavelength traveling direction of the high-frequency signal.

11. The high-frequency module as set forth in claim 10, wherein the woven glass fabric is formed by warding the glass fibers into a mesh pattern whose pitch is smaller than λe/10 (λe: effective wavelength of high-frequency signal).

12. The high-frequency module as set forth in claim 10, wherein the woven glass fabric is form-ed from the glass fibers woven in a mesh pattern inclined at an angle between 10 and 80 deg. in the wavelength traveling direction of the high-frequency signal.

13. The high-frequency module as set forth in claim 10, wherein the organic substrate in the base substrate block is formed from an organic material selected from materials including liquid crystal polymer, benzocyclobutene, polyimide, polynorbornen, polyphenylether, polytetrafluoroethylene, BT-resin, which is low in dielectric constant and low in loss, or each of these resins having ceramic powder dispersed therein and provided integrally on the woven glass fabric as a core.

14. The high-frequency module as set forth in claim 10, wherein the passive elements include an inductor, capacitor and resistor, which are formed by film forming.
